(19) United States
(12) Patent Application Publication
(10) Pub. No.: US 2015/0059389 A1
(43) Pub. Date: Mar. 5, 2015

(54) SYSTEM AND APPARATUS FOR HEATING OR COOLING HAVING FLUID COOLED ELECTRONICS

(71) Applicant: Trane International Inc., Piscataway, NJ (US)

(72) Inventors: Ye Ting Liu, Jingjiang (CN); Bryan Richard Teichgraeber, Tyler, TX (US); Arvind Chitrala, Tyler, TX (US); Beth Robinson, Tyler, TX (US); Ray Weaver, Tyler, TX (US); Bobby Dubley, Whitehouse, TX (US)

(21) Appl. No.: 14/478,749

(22) Filed: Sep. 5, 2014

Related U.S. Application Data
(60) Provisional application No. 61/874,147, filed on Sep. 5, 2013.
(60) Provisional application No. 61/874,867, filed on Sep. 6, 2013.

(51) Int. Cl. H05K 7/20

(52) U.S. Cl. CPC H05K 7/20354
USPC 62/259.2

(57) ABSTRACT

A refrigeration unit is disclosed that includes a fluid cooled power electronics package. The refrigeration unit can include a variable speed motor used to drive a compressor. The variable speed motor is driven by the fluid cooled power electronics where the fluid used to cool the electronics is working fluid from the refrigeration cycle of the refrigeration unit. A conduit is configured to route cooling fluid to the electronics. In one embodiment the electronics can be removed without the need to disassemble the conduit that carries the cooling fluid to the power electronics.

### PRIORITY

The present application claims priority to U.S. Provisional Patent Application No. 61/874,147, filed Sep. 5, 2013 and to U.S. Provisional Patent Application No. 61/874,867, filed Sep. 6, 2013, the disclosures of which are incorporated herein by reference.

### TECHNICAL FIELD

The present invention generally relates to fluid cooled power electronics in systems such as those for heating or cooling, and more particularly, but not exclusively, to active fluid cooling of power electronics in a heating or cooling system such as an outdoor refrigeration unit.

### BACKGROUND

Providing enhanced cooling capabilities to power electronics in heating, ventilation, and air conditioning (HVAC) systems remains an area of interest. Some existing systems have various shortcomings relative to certain applications. For instance, while air cooling has long been an industry standard, air cooling can be ineffective as applied to high power or otherwise highly heat productive systems. Accordingly, there remains a need for further contributions in this area of technology.

### SUMMARY

One embodiment of the present invention is an assembly having a replaceable high temperature power electronics cooled by a refrigerant where a coolant line for the refrigerant need not be disassembled to service the power electronics. Other embodiments include apparatuses, systems, devices, hardware, methods, and combinations for maintaining a conduit used to cool power electronics substantially in place when the power electronics are serviced. Further embodiments, forms, features, aspects, benefits, and advantages of the present application shall become apparent from the description and figures provided herewith.

### BRIEF DESCRIPTION OF THE DRAWINGS

FIG. 1 illustrates one embodiment of a system for heating or cooling;

FIG. 2 illustrates one embodiment of a power electronics control box suitable for use in the system of FIG. 1;

FIG. 3 illustrates a different view of the power electronics control box and part of the system of FIG. 1;

FIG. 4 illustrates yet a different view of the power electronics control box and part of the system;

FIG. 5 illustrates yet a different view of the power electronics control box, including control box layout features according to one embodiment.

### DETAILED DESCRIPTION OF ILLUSTRATIVE EMBODIMENTS

For the purposes of promoting an understanding of the principles of the invention, reference will now be made to the embodiments illustrated in the drawings and specific language will be used to describe the same. It will nevertheless be understood that no limitation of the scope of the invention is thereby intended. Any alterations and further modifications in the described embodiments, and any further applications of the principles of the invention as described herein are contemplated as would normally occur to one skilled in the art to which the invention relates.

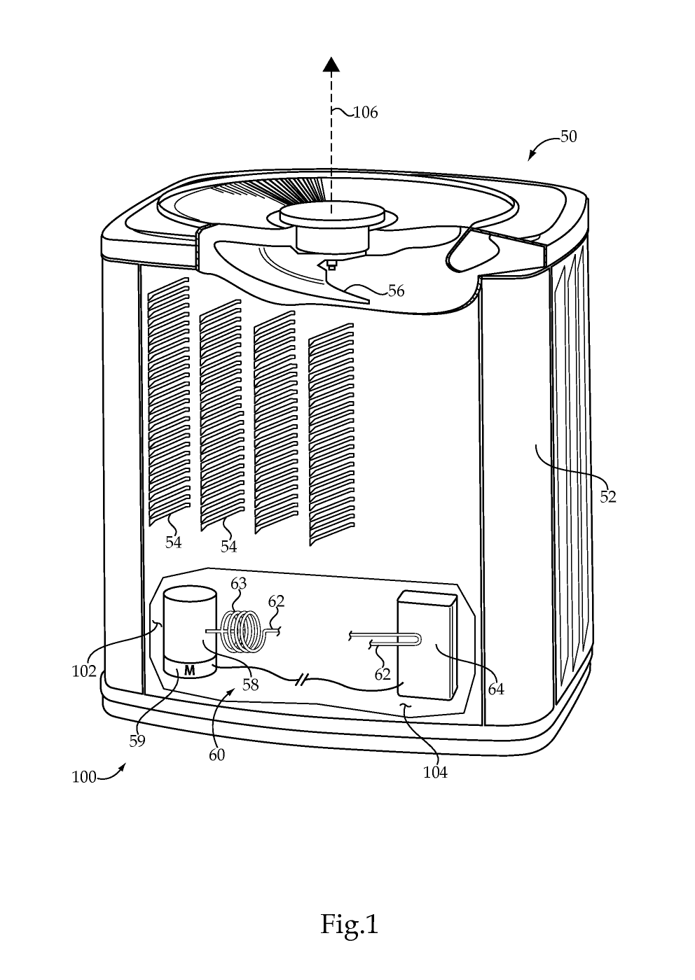

With reference to FIG. 1, one embodiment of a system 100 for heating or cooling a conditioned space such as a building interior includes an outdoor refrigeration unit 50. An external refrigerant coil such as an evaporator coil, blower, and such other components of system 100 as might be used in system 100 apart from unit 50 are well known and thus not depicted in FIG. 1. Unit 50 is illustrated having an outer housing 52 that includes a number of vent openings 54 structured to admit a flow of air between an interior and exterior of outdoor refrigeration unit 50. Unit 50 depicted in the illustrated embodiment includes a fan 56 rotatable about a vertical axis 106 and structured to draw air through openings 54 so as to generate the flow of air into an interior of unit 50 to assist in cooling refrigerant as will be described further below. As used herein, an outdoor refrigeration unit includes devices such as air conditioners and heat pumps as it will be appreciated that heat pumps can be operated as air conditioners.

Outdoor refrigeration unit 50 can take on many forms, and in the illustrated embodiment is depicted as a split air conditioning unit in which unit 50 houses a compressor 58 structured to elevate a pressure of the cooling refrigerant and condenser 60 structured to extract heat from the cooling refrigerant. Compressor 58 includes an electric compressor motor 59. Condenser 60 may include a refrigerant coil 63, within housing 52, for conveying the refrigerant fluid so as to exchange heat with the flow of air, and is in fluid communication with compressor 58. Although unit 50 can be a split system as discussed above, unit 50 can also include a full system having all traditional refrigeration components such as might be included in a window air conditioning unit.

Compressor 58 is in fluid communication with condenser 60 through a refrigerant conduit 62. In a practical implementation strategy, conduit 62 may be in fluid communication with at least one of refrigerant coil 63 and compressor 58. Conduit 62 can be made of a variety of materials and have a variety of cross sectional shapes. Conduit 62 is formed of copper in a practical implementation strategy. Unless discussed to the contrary, the term “conduit” can include singular or multiple passageways that together form a flow path for the cooling refrigerant. Conduit 62 can be found between components such as compressor 58 and condenser 60, and in some forms can also extend to locations/components beyond either of compressor 58 and/or condenser 60. In such an example where multiple instances of conduit 62 are found between different components of a refrigeration system that together form a pathway, the conduit can be referred to as a conduit system. Some split air conditioning systems when installed can include a conduit system that provides for a refrigerant outlet and a refrigerant inlet to unit 50. In such an example, the refrigerant outlet can convey cooling refrigerant to an evaporator located outside of unit 50. Such an evaporator can be located in an interior room of a building such as a house or business where an expansion valve or other useful device can create a rapid pressure and temperature loss of the cooling refrigerant to cool the interior room. When a split air conditioning unit 50 is installed and connected to an evaporator located in an interior of a building, the conduit system can generally refer to a closed path of conduit that is used to circulate cooling refrigerant between all components of a working refrigeration system.

Compressor 58 can be driven by electric motor 59, which can be a variable speed motor. In one form the variable speed motor is a DC motor that can be of the brushless kind, but other kinds are also contemplated. The variable speed motor can be coupled with a power electronics unit or DC drive 64 to provide necessary power management, such as through switching, to provide an adequate source of power to motor 59. Unless stated to the contrary, the terms “power electronics” and “power electronics unit” are intended to cover DC drives, and any mention of power electronics herein will not be construed such that it does not cover DC drives. In one embodiment power electronics unit 64 can include one or more transistors, such as IGBT's, that provide the necessary power to operate the motor at variable speeds. During operation the power electronics can become very warm and a source of cooling can be provided via heat transfer between the DC drive 64 and cooling refrigerant passing through conduit 62. The conduit 62 can be placed in thermal contact directly or through an intermediary with the drive 64.

The power electronics or DC drive can be accessible via an external door provided in an outer housing of the unit 50 for servicing and/or maintenance. The external door can be a panel or other like device that can be affixed to the air conditioning unit such as through a hinge mechanism, rails, slotted attachments, screws, bolts, etc. In some forms the power electronics can be located in a control box internal to the unit 50 but otherwise accessible via the external door discussed above. It can be noted that part of housing 52 is free of vent openings generally in the vicinity of power electronics unit 64. While such a feature might or might not be evident in a commercial embodiment, the absence of openings is presented to illustrate the nature of air flow and lack of air flow through a first internal space 102 in housing 52, and a second internal space 104, respectively. In a practical implementation strategy, refrigerant coil 63 and compressor 58 are positioned within first internal space 102, and power electronics unit 64 is positioned within second internal space 104. Compressor 58 can also be located in a compartment separate from a high rate flow path associated with the fan 56 and condenser 60. A through space, not specifically illustrated in FIG. 1, extends between first interval space 102 and interval space 104, the significance of which will be apparent from the following description.

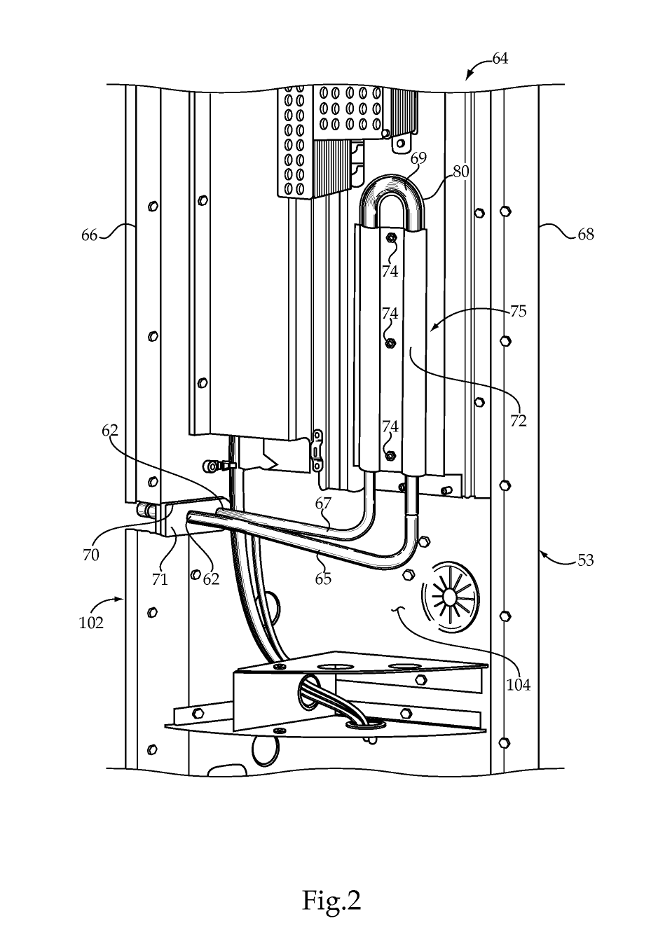

Turning now also to FIG. 2, there is shown one embodiment of an interior portion of unit 50 in which is disposed power electronics unit 64. Though only a portion of the interior is shown in FIG. 2, space 104 may be located in a corner of housing 52 of outdoor refrigeration unit 50. Walls 66 and 68 form two sides of the control box, with the remaining sides being formed by housing 52. Walls 66 and 68 each include a flange with fastener openings shaped to abut a corner of housing 52. In some forms walls 66 and 68 are one continuous wall. The walls 66 and 68 are coupled to an outer housing of the unit 50 to form an enclosure that can be referred to as a control box 53. Control box 53 can be set apart from high air flow rate paths associated with fan 56 and condenser 60 such that relatively little to no cooling air is circulated within control box 53.

Inside control box 53, conduit 62 is routed to deliver a flow of cooling refrigerant into control box 53 such that it is placed in thermal contact with power electronics 64. Thereafter conduit 62 is routed to deliver the flow of cooling refrigerant out of control box 53. Conduit 62 is routed through a cutout or through space 70 in wall 66 in which is located a securing device 71 that fits in cutout 70 to capture conduit 62. It can be seen that conduit 62 extends from first internal space 102 into and out of second internal space 104 via cutout 70. Cutout 70 can be located such that it extends to the end of wall 66, but different embodiments can locate cutout 70 elsewhere. Conduit 62 can deliver refrigerant fluid into control box 53 from any component of outdoor refrigeration unit 50, and can discharge the refrigerant fluid to any other component. For example, conduit 62 can receive refrigerant fluid from a compressor and deliver to a condenser; conduit 62 can receive refrigerant from a condenser and deliver to an evaporator; conduit 62 can receive refrigerant from the evaporator and deliver to the compressor. Any other variation of routing is also contemplated, including routing only a portion of the refrigerant fluid to control box 53 relative to a total refrigerant mass flow.

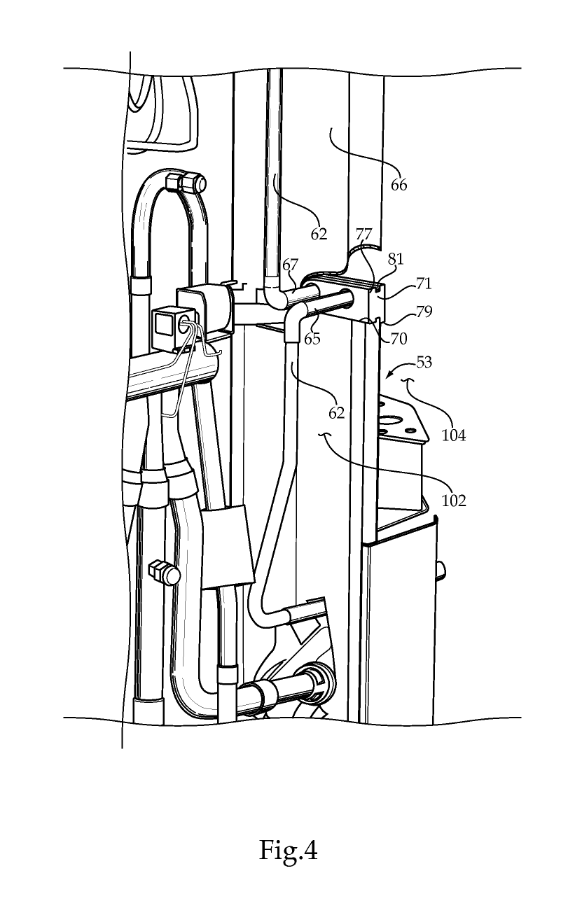

Securing device 71 can be used to provide support and/or positively secure conduit 62 to wall 66, as well as attenuating vibrations. From compression 58, or as experienced during shipping. In one embodiment securing device 71 takes the form of a grommet that fills cutout 70 and captures conduit 62, but other methods of securing conduit 62 can also be used. The grommet can be a single piece or it can take the form of multiple pieces. For example, separate grommet halves can be used to sandwich wall 66 therebetween and secure and/or support conduit 62. Device 71 can be formed of natural rubber, or other rubber-like materials. In one embodiment, device 71 is formed of EPDM. In FIG. 4, a minor lobe 77 of the grommet/device 71 is shown positioned upon a first side of wall 66, whereas a larger major lobe 79 is shown positioned upon a second side of wall 66, within space 104. A groove 81 receives edges of wall 66 forming cutout 70. Additional and/or alternative techniques such as packing, screws, clips, etc can also be used to secure conduit 62 to one or both of the walls 66 and 68. Although the grommet fits into a single cutout in wall 66 to pass two separate conduit portions, some embodiments can include two cutouts having two securing devices such that a single conduit is passed through each cutout and secured to the wall(s) through the two securing devices.

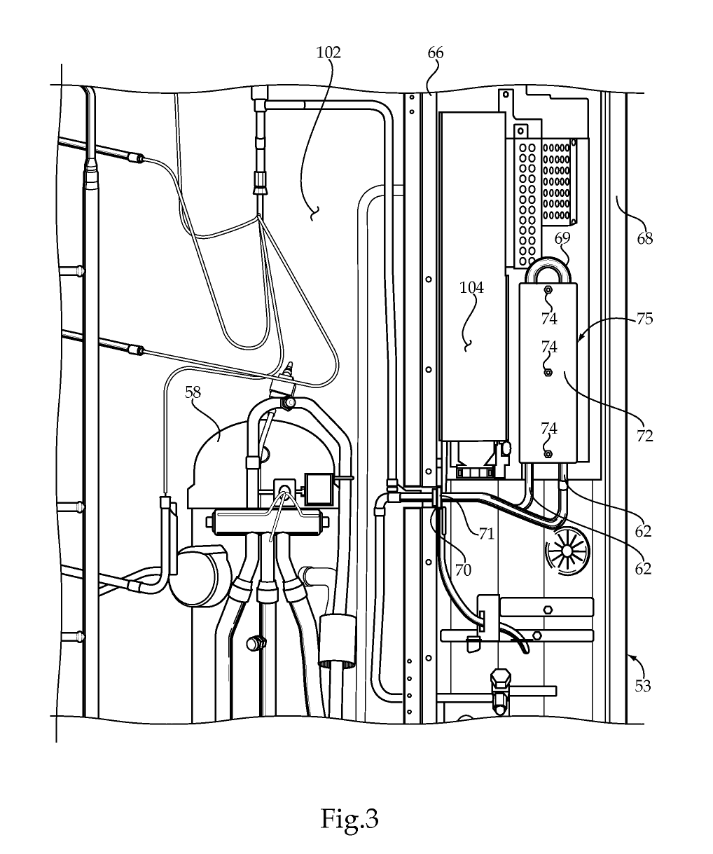

Referring also to FIGS. 3 and 4, there are shown additional views in which a supply segment 65, a return segment 67, and a cooling segment 69 of conduit 62 are labeled. The terms “supply” and “return” are chosen as a matter of convenience, and either segment of conduit 62 could be used to deliver refrigerant fluid or return refrigerant fluid to and from control box 53. It can be noted that each of supply, return, and cooling segments 65, 67, and 69 are tubular in form, and segments 65 and 67 each extend through through space 70. Conduit 62 may be monotubular such that a single uniformly shaped and uninterrupted fluid passage extends into and out of internal space 104. Cooling segment 69 may have a U-shape, and may be vertically oriented generally in parallel with axis 106 shown in FIG. 1. In a practical implementation strategy, cooling segment 69 may be sized and positioned such that hot spots in unit 64, for instance corresponding to IGBT locations, are generally aligned with or at least overlapped by the straight vertical runs of conduit 62 that form the legs of the U-shape in cooling segment 69.

Conduit 62 is attached to a heat sink 72 which can be made of a variety of materials and is used to aid in heat transfer between power electronics unit 64 and cooling refrigerant fluid conveyed through conduit 62. Such a cooling aid can be used to cool high temperature components associated with the power electronics such as IGBT's and copper coils. Heat sink 72 can include an internal passageway for the conduit 62 which can be formed in some embodiments by two separate heat sink halves that sandwich the conduit 62. In some forms heat sink 72 is a cover plate that captures conduit 62 between it and the power electronics. Heat sink 72 can be an aluminum plate in some embodiments, but other shapes and materials are contemplated herein.

Heat sink 72 is releaseably attached to power electronics 64 via fasteners 74 such that conduit 62 need not be disassembled when servicing power electronics 64. In some embodiments conduit 62 and/or heat sink 72 need not be moved, or need be moved an insubstantial amount when power electronics 64 is serviced such that conduit 62 need not be disassembled (nor refrigerant drained) to remove the electronics. Fasteners 74 can take a variety of forms and can have any number that are used. Three fasteners 74 in a regular vertical spacing, and equally torqued, provides a practical implementation strategy. In some embodiments the fasteners are screws or bolts, but other embodiments can include clips, slotted attachments, rails, etc and combinations thereof. It will be appreciated that heat sink 72 and fasteners 74 form a clamping mechanism 75 coupling conduit 62 to power electronics unit 64. Clamping mechanism 75 has a clamped state holding cooling segment 62 against power electronics unit 64 so as to maintain the thermal contact, and a release state where power electronics unit 64 can be decoupled from conduit 62. Fasteners 74 can be engaged and disengaged to switch clamping mechanism 75 between the clamped state and the release state.

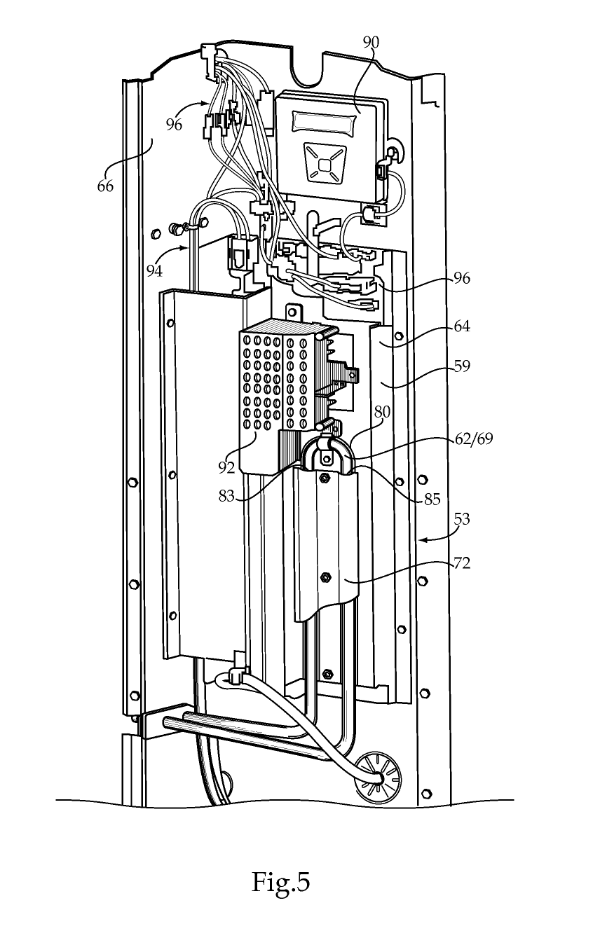

With continued reference to FIGS. 1-4, but also now to FIG. 5, the present disclosure further contemplates a combination of unique features relating to layout of control box 53, including an arrangement of various components in space, integration of separate components into one, and design for manufacture and assembly. Among other things, such features are together contemplated to hasten and simplify assembly and reduce risk of mistakes in assembly, reduce electromagnetic interference (EMI), and optimize heat transfer out of control box 53 according to the cooling techniques set forth herein.

Current high seasonal energy efficiency ratio (SEER) products as used in outdoor compressors for heating ventilation and cooling systems typically have multiple circuit boards and external components (e.g., capacitor, relay, transformers, etc.) mounted in the control panel area with high and low voltage AC as well as low voltage DC wiring comingling in a confined space. Mounting individual components and circuit boards to the control panel with intertwined wires causes EMI, risk of miswiring, control board resetting issues, and reliability problems. There is also high takt time and labor costs associated with assembling individual components and the necessary wiring to the panel. It also reduces the number of connections necessary at run test. Warranty and field costs increase as a result of the issues listed above.

In control box 53 according to the present disclosure, poka-yoke electrical connections (not numbered) are used throughout, as is shielded harness for compressor wiring 94 to eliminate EMI noise. A communication display assembly 90 is also provided for field trouble shooting, and high voltage wires 94 versus low voltage wires 96 are routed separately for better controls reliability. A PFC choke 92 is integrated onto power electronics unit 64, and mounted and supported upon a housing 59 thereof. Also shown in FIG. 5 is a U-shaped groove 80 formed in housing 59, where it can be seen that conduit 62, and in particular cooling segment 69, is within groove 80. Heat sink plate 72 has a first groove 83 and a second groove 85 therein, with portions of conduit 62 forming legs of U-shaped cooling segment 69 being positioned within first and second grooves 83 and 85. In FIG. 5, heat sink plate 72 is shown in cutaway to illustrate certain of these features. When unit 50 is completely assembled for service, control box 53 may be completely sealed and meets agency requirements including rain tests.

As alluded to above, certain known control box arrangements employ multiple components and multiple circuit boards. In control box 53, the multiple circuit boards have all been included in the design of the integrated inverter drive/power electronics unit 64. A circuit board 96 is visible in FIG. 5, and may be one of three circuit boards or potentially a still greater number all positioned within unit 64. This eliminates the need for excessive wire routings throughout the control box and reduces opportunities for miswiring. Power electronics unit 64 is easy to replace and assemble, as discussed herein, and can now have one SKU instead of multiple SKU's for multiple components.

As also noted above, in order to eliminate EMI issues the high and low voltage AC and DC wires are separated through several approaches. Previous control box designs made little attempt at separating low and high voltage wiring. Sensors have been found to report incorrect data due to EMI issues, however. According to the present disclosure, in control box 53 the layout is such that high voltage wires 94 enter at the bottom, or a lower location, and low voltage wires 96 enter through a slot in the top of the box, such as a higher location near the top of wall 66. The ability to separate low voltage sensors from high voltage wires eliminates the need to spend additional money on shielded sensor wires. In order to minimize voltage drop and EMI noise, the compressor harness is optimized to be as short as possible. The communications display assembly (“CDA”) 90 is a substitution for the typical LED light configuration on or in association with unit 64 that helps a technician determine the health of the system, and may be located at the top of control box 53 approximately as shown so that it is easily accessible and removable. As discussed above, the drive (unit 64) is cooled by routing the liquid tubing (conduit 62) into control box 53 and clamping it to the drive. This allows the drive to be easily removed from control box 53 for servicing or replacement. Wire lengths are optimized so as to prevent excessive wire bundling inside of the box, and are routed directly to their terminations. All connectors in the box are poka-yoke so as to prevent miswiring as noted above. Yet another feature relates to routing of the low voltage wires out of control box 53. In a practical implementation strategy, low voltage wires 96 gain entry/exit via a slot shaped in such a way that the low voltage wires are captured and there is no longer a potential for them to be pinched between control box 53 and a top of housing 52 of unit 50, or otherwise pinched between components. Also in a practical implementation strategy, the only electronic components in the control box are the integrated inverter drive/unit 64 and communications display assembly 90.

It can further be noted that in order to eliminate EMI issues, the high and low voltage wires are separated through several means. The layout of control box 53 was designed so that the high voltage wires enter through the bottom and the low voltage wires enter through a slot in the top of the box so that they co-mingle as little as possible. The DC and AC wires must also be separated, so the high voltage AC input wires enter the control box through a sheet metal barrier that separate them from the DC output wires coming from the drive. The high voltage AC wires then travel to the top of the box through a channel that exists between the drive enclosure and control panel. Since the channel is made of metal on all sides, this provides a shield so that the electromagnetic emissions from the high voltage wires are contained. The low voltage sensors coming from a different part of the system travel up the back side of the control panel so as not to have interference from the high voltage AC wires. The ability to separate the low voltage sensors from the high voltage wires eliminates the need to spend additional money on shielded sensor wires. The compressor harness may be optimized to be as short as possible in order to minimize voltage drop and EMI noise. In order to maintain that short length, it is routed through the bottom of the box instead of over the top as is usually done.

The communications display assembly (CDA) is located at the top of the control box so that it is easier for a technician to stand and diagnose the system. Through the use of captive screws and locking features on tabs it can easily be removed. It also has extra wire length so that a technician can hold it in his/her hands while using it. The CDA is also in the low voltage section of the control box so that a technician does not have to place his hands near dangerous high voltage wires.

The low voltage wire entry slot is shaped like an upside down light bulb so that the wires can slip through individually, but when they are wire tied together the narrow opening prevents them from popping out. This eliminates the potential for wires getting pinched between the box and the top cover.

It is appreciated that integrated drives may be utilized to reduce the number of components located in control boxes. Further, the high voltage and low voltage wires may be separated between the left and right sides of the box instead of the top and bottom portions. Moreover, air cooled heat sinks could be utilized instead of liquid cooling. In addition, the embodiments disclosed herein could be incorporated in residential or commercial HVAC units, or variable speed air compressors.

Though the description herein is written from the perspective of a refrigeration unit, it will be appreciated that the techniques described herein are also applicable to other devices such as air compressors, hydronics, automobiles, power electronics, and high power LED's. While the invention has been illustrated and described in detail in the drawings and foregoing description, the same is to be considered as illustrative and not restrictive in character, it being understood that only the preferred embodiments have been shown and described and that all changes and modifications that come within the spirit of the invention are desired to be protected. It should be understood that while the use of words such as preferable, preferably, preferred or more preferred or practical utilized in the description above indicate that the feature so described may be more desirable, it nonetheless may not be necessary and embodiments lacking the same may be contemplated as within the scope of the invention, the scope being defined by the claims that follow. In reading the claims, it is intended that when words such as “a,” “an,” “at least one,” or “at least one portion” are used there is no intention to limit the claim to only one item unless specifically stated to the contrary in the claim. When the language “at least a portion” and/or “a portion” is used the item can include a portion and/or the entire item unless specifically stated to the contrary. Unless specified or limited otherwise, the terms “mounted,” “connected,” “supported,” and “coupled” and variations thereof are used broadly and encompass both direct and indirect mountings, connections, supports, and couplings. Further, “connected” and “coupled” are not restricted to physical or mechanical connections or couplings.

What is claimed is:

1. A system for heating or cooling a conditioned space comprising:
an outdoor unit including a housing having a plurality of vent openings structured to admit a flow of air, a refrigerant coil within the housing for conveying refrigerant fluid to exchange heat with the air, and a compressor in fluid communication with the refrigerant coil and having an electric compressor motor;
the outdoor unit further including a power electronics unit structured to drive the electric compressor motor, and a refrigerant conduit in fluid communication within the housing with at least one of the refrigerant coil and the compressor;
the housing further having therein a first internal space where the refrigerant coil and compressor are positioned and in fluid communication with the plurality of vent openings, a second internal space where the power electronics unit is positioned, and a through space extending between the first and second internal spaces;
the refrigerant conduit extending between the first internal space and the second internal space via the through space, and including a cooling segment in thermal contact with the power electronics unit; and
a clamping mechanism having a clamped state holding the cooling segment against the power electronics unit so as to maintain the thermal contact, and a release state where the power electronics unit can be decoupled from the refrigerant conduit.

2. The system of claim 1 wherein the cooling segment has a U-shape.

3. The system of claim 2 wherein the power electronics unit has a U-shaped groove formed therein, and the cooling segment is within the U-shaped groove.

4. The system of claim 3 wherein the clamping mechanism includes a heat sink plate having first and second parallel grooves, and the cooling segment is positioned partially within each of the parallel grooves and the U-shaped groove and sandwiched between the heat sink plate and the power electronics unit in the clamped state.

5. The system of claim 1 wherein the refrigerant conduit includes a supply segment and a return segment each extending through the through space, and the cooling segment connects the supply and return segments, and wherein each of the supply, return, and cooling segments is tubular in form.

6. The system of claim 5 further comprising a fan structured to generate the flow of air via rotation about a vertical axis, and wherein the cooling segment has a U-shape and is vertically oriented within the second internal space.

7. An apparatus comprising:
an outdoor refrigeration unit having an outer housing including a plurality of vent openings structured to admit a flow of air into an internal space of the outer housing to cool a refrigerant fluid as it is used in a refrigeration cycle associated with the outdoor refrigeration unit;
a power electronics unit located internal to the outer housing of the outdoor refrigeration unit and structured to drive a compressor motor;
a refrigerant conduit for conveying the refrigerant fluid, the refrigerant conduit disposed internal to the outdoor refrigeration unit, the refrigerant conduit in thermal contact with the power electronics unit to transfer heat between the power electronics unit and the refrigerant fluid;
a wall of the outdoor refrigeration unit having a surface to which is releasably mounted the power electronics unit; and
a securement device disposed in a through space internal to the outdoor refrigeration unit, the securement device capturing and mounting the refrigerant conduit within the outdoor refrigeration unit;
wherein the securement device secures the refrigerant conduit in place so that the power electronics unit can be decoupled from the refrigerant conduit for servicing and removed from the outdoor refrigeration unit without disassembly of the refrigerant conduit such that the refrigerant conduit remains substantially in place during removal of the power electronics.

8. The apparatus of claim 7, which further includes a refrigerant compressor having a compressor motor disposed internal to the outdoor refrigeration unit and structured to compress the refrigerant fluid as part of the refrigeration cycle.

9. The apparatus of claim 8, wherein the refrigerant conduit receives refrigerant fluid from a condenser and passes the fluid to an evaporator.

10. The apparatus of claim 8, wherein the refrigerant conduit receives refrigerant fluid from an evaporator and passes the fluid to the compressor.

11. The apparatus of claim 7, wherein the securement device is a grommet, wherein the grommet permits the refrigerant conduit to be hermetically sealed during servicing and removal of the power electronics unit, and wherein the outdoor refrigeration unit is an outdoor air conditioning unit.

12. The apparatus of claim 11, wherein the grommet encloses the hermetically sealed refrigerant conduit and fills the through space between the refrigerant conduit and an outer edge of the through space.

13. The apparatus of claim 11, wherein the grommet includes provision for passage of two portions of the hermetically sealed refrigerant conduit.

14. The apparatus of claim 13, which further includes a heat transfer material connected to the refrigerant conduit and coupled to the power electronics unit when installed.

15. The apparatus of claim 13, wherein the through space is defined by the wall of the outdoor refrigeration unit.

16. The apparatus of claim 15, wherein the wall forms an electronics enclosure for separating the power electronics unit from a fan passageway internal to the outdoor refrigeration unit for the passage of a cooling air used with a condenser.

17. An apparatus comprising:
a power electronics package having high temperature components;
a housing that at least partially encloses the high temperature components, the housing have a through passage;
a conduit for the passage of a cooling fluid and routed through the through passage, the conduit in thermal contact with the power electronics; and
a grommet positioned proximate the through passage and structured to retain the conduit with the housing such that the conduit can substantially remain in place during removal of the power electronics.

18. The apparatus of claim 17, which further includes an outer housing which encloses a fan used to cool the cooling fluid.

19. The apparatus of claim 17, which further includes a condenser useful to transfer heat from the cooling fluid.

20. The apparatus of claim 17, which further includes a compressor structured to raise a temperature of the cooling fluid.

21. The apparatus of claim 1 wherein the housing, condenser, and compressor form an outdoor refrigeration unit.

22. An apparatus for heating or cooling a conditioned space comprising:
an outdoor unit including a unit housing, a compressor within the unit housing and having an electric compressor motor, and a refrigerant coil;
the outdoor unit further including a power electronics unit structured to drive the electric compressor motor and including a drive housing and a choke supported on the drive housing;
a refrigerant conduit in fluid communication within the housing with at least one of the compressor and the refrigerant coil, and the refrigerant conduit being in thermal contact with the drive housing and configured to convey a refrigerant fluid so as to transfer heat out of the drive housing.
